(19) United States
(12) Patent Application Publication
(10) Pub. No.: US 2009/0108309 A1
(43) Pub. Date: Apr. 30, 2009

(54) CMOS IMAGE SENSOR AND METHOD FOR MANUFACTURING THE SAME

(76) Inventor: Jin-Ho Park, Gangnam-gu (KR)

Correspondence Address: SHERR & VAUGHN, PLLC, 620 HERNDON PARKWAY, SUITE 200, HERNDON, VA, 20170, US

(21) Appl. No.: 12/255,061

(22) Filed: Oct. 21, 2008

(30) Foreign Application Priority Data
Oct. 25, 2007 (KR) 10-2007-0107761

(51) Int. Cl. H01L 31/00; H01L 21/00

(52) U.S. Cl. 257/292; 438/70; 257/E31.001; 257/E21.001

(57) ABSTRACT

A CMOS image sensor, which can monitor accurate overlay information even when a dual microlens is employed, and a method for manufacturing the same are disclosed. The CMOS image sensor includes a substrate having a photosensitive element formed therein; a light shield layer formed over the substrate and having a portion spatially corresponding to the photosensitive element; a color filter formed over the light shield layer; and a microlens having a first microlens portion and a second microlens portion formed spaced apart over the color filter, the second microlens portion being formed in a region surrounded by the first microlens portion.

The present application claims priority under 35 U.S.C. §119 to Korean Patent Application No. 10-2007-0107761 (filed on Oct. 25, 2008), which is hereby incorporated by reference in its entirety.

### BACKGROUND

Generally, a CMOS image sensor includes a photosensitive element for receiving light and transforming the light into electric signals according to the quantity of the received light and a logic signal region for transforming the electric signals from the photosensitive element into data. The larger the quantity of the light received by the photosensitive element, the higher the photosensitivity of the image sensor. Thus, in order to increase photosensitivity, there has been many endeavors to increase the fill factor occupied by the photosensitive element in the region of the image sensor. Recently, there have been many studies of light-collecting techniques by which the pathways of the incident lights injecting to the regions other than the photosensitive element are changed and collected in the photosensitive element. Further, much effort is recently being made to maximize the performance of a microlens on which light is firstly incident, along with these light-collecting techniques.

As illustrated in example FIG. 3, an overlay of a single microlens 1 on which light is firstly incident is formed on and/or over a light shield layer such as upper metal 2. If one microlens 1 is formed, information of overlay with upper metal 2 can be easily found. The realization of the accuracy of this overlay is a considerably important factor in association with the recent trend toward a decrease in the size of pixels.

However, a technique for forming microlenses in a dual-type has been recently developed to reduce the gap between microlenses (to realize a so-called zero gap). While information of overlay between any one of the dual microlenses and an upper metal can be easily found, information of overlay between the dual microlenses cannot be accurately found when using dual microlenses. Accordingly, many defects occur during the progression of the process, including the generation of a bridge between microlenses.

### SUMMARY

Embodiments relate to a CMOS image sensor and a method for manufacturing a CMOS image sensor employing the dual microlens that monitors information of overlay even between the lenses of the dual microlens.

Embodiments relate to a CMOS image sensor that may include at least one of the following: a semiconductor substrate in which at least one optical sensing element is formed; a light shield layer having an opened region corresponding to the photosensitive element formed in the semiconductor substrate; an interlayer insulating film formed between the semiconductor substrate and the light shield layer; a color filter formed on and/or over the light shield layer; and a first microlens and a second microlens formed on and/or over the color filter, the second microlens being disposed in the region where the first microlens is formed.

Embodiments relate to a method for manufacturing a CMOS image sensor that may include at least one of the following: forming at least one photosensitive element in a semiconductor substrate; and then forming an interlayer insulating film, a light shield layer, and an element protecting film on and/or over the semiconductor substrate; and then forming a color filter on and/or over the element protecting film; and then forming a first microlens on and/or over the color filter; and then forming a second microlens in the region where the first microlens is formed; and then monitoring overlay between the first microlens and the second microlens after the step of forming a second microlens.

Embodiments relate to a method for manufacturing a CMOS image sensor that may include at least one of the following: forming a photosensitive element in a substrate; and then forming a light shield layer over the substrate and having a portion spatially corresponding to the photosensitive element; and then forming a color filter over the light shield layer; and then forming a microlens having a first microlens portion and a second microlens portion spaced apart over the color filter, the second microlens portion being formed in a region surrounded by the first microlens portion.

Embodiments relate to a method that may include at least one of the following: providing a substrate having a photosensitive element and a field insulating film formed therein; and then forming a first interlayer insulating film over the substrate including the photosensitive element and the field insulating film; and then forming a second interlayer insulating film formed over the first interlayer insulating film; and then forming a light shield layer in the second interlayer insulating film; and then forming an element protecting film over the second interlayer insulating film including the light shield layer; and then forming a color filter over the element protecting film; and then forming a microlens by forming a first microlens portion and a second microlens portion spaced apart over the color filter such that the second microlens portion is surrounded by the first microlens portion; and then monitoring overlay alignment between the first microlens portion and the second microlens portion.

Embodiments relate to an image sensor that may include at least one of the following: a substrate having a photosensitive element formed therein; a light shield layer formed over the substrate and having a portion spatially corresponding to the photosensitive element; a color filter formed over the light shield layer; and a microlens having a first microlens portion and a second microlens portion formed spaced apart over the color filter, the second microlens portion being formed in a region surrounded by the first microlens portion.

In accordance with embodiments, since the CMOS image sensor employs a dual microlens structure, the pixel size of the CMOS image sensor can be further reduced by reducing the gap between the dual microlenses. Furthermore, embodiments can provide monitoring of information of overlay even between the microlenses.

### DRAWINGS

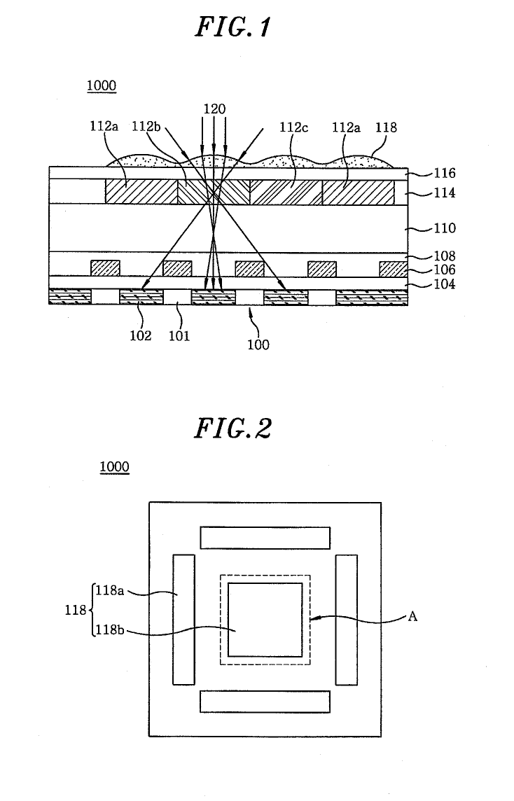

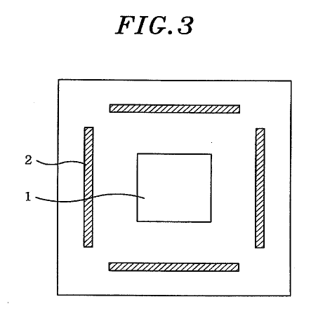

Example FIGS. 1 and 2 illustrate a CMOS image sensor in accordance with embodiments.

Example FIG. 3 illustrates an overlay when a single microlens is formed.

### DESCRIPTION

As illustrated in example FIG. 1, CMOS image sensor 1000 in accordance with embodiments includes semiconductor substrate 100 having at least one photosensitive element 102 and field insulating film 101 formed therein. Photosensitive element 102 may be formed of a photogate or photodiode. Light shield layer 106 is formed on and/or over substrate 100 including field insulating film 101 and photosensitive element 102. A plurality of color filters 112a, 112b, and 112c are formed on and/or over light shield layer 106. Microlens array 118 is formed on and/or over color filters 112a, 112b, and 112c.

First interlayer insulating film 104 and second interlayer insulating film 108 for insulating photosensitive element 102 and field insulating film 101 are formed on and/or over semiconductor substrate 100. Light shield layer 106 may be formed on and/or over first interlayer insulating film 104. Light shield layer 106 may be formed in second interlayer insulating film 108 in order to prevent light from entering a region other than photosensitive element 102. Element protecting film 110 is formed on and/or over second interlayer insulating film 108. Color filters 112a, 112b, and 112c are formed in insulating layer 114 and on and/or over element protecting film 110. As the materials of color filters 112a, 112b and 112c of red, green and blue, photoresists dyed in colors capable of absorbing only the light of a specific wavelength may be used. Planarizing film 116 made of a photoresist may be formed on and/or over color filters 112a, 112b, and 112c in order to compensate for the surface roughness of color filters 112a, 112b, and 112c.

Microlenses 118 may be composed of polymer-type resins. As for the light passing through microlenses 118, red, green and blue light are filtered through the red, green and blue color filters 112a, 112b and 112c, and the filtered light is focused on and/or over photosensitive element 102 disposed at lower ends of color filters 112 through element protecting film 110 and first interlayer insulating film 104 and second interlayer insulating film 108. Light shield layer 106 plays the role of shielding the incident light so as not to deviate to other light pathways.

As illustrated in example FIG. 2, a plane view schematically illustrating a microlens region of the CMOS image sensor in accordance with embodiments illustrated in example FIG. 1. Each microlens 118 is formed having a dual microlens structure including first microlens portion 118a and second microlens portion 118b. That is to say, the pixel size of the CMOS image sensor is becoming gradually smaller with the recent trend of high capacitance. Thus, microlenses 118 in accordance with embodiments are formed in a dual-type structure in order to further reduce the gap between the microlenses, i.e., to realize a zero gap. However, it is difficult to collect information of overlay between the microlenses included in a dual microlens as a zero gap is formed between the microlenses. In accordance with embodiments, however, the CMOS image sensor collects information of overlay between any one of the dual microlenses and an upper metal.

Accordingly, first microlens portion 118a is formed around predetermined region A, and second microlens portion 118b is formed in predetermined region A, thus making it possible to collect information of overlay between first microlens region 118a and the second microlens 118b. Since the method may further include monitoring overlay between first microlens portion 118a and second microlens portion 118b after the formation microlens 118, information of overlay between the microlenses can be easily found while realizing a zero gap by forming a dual microlens. Therefore, the formation of a bridge caused by a lens shift is prevented, thereby drastically improving the yield of the CMOS image sensor.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a substrate having a photosensitive element formed therein;
a light shield layer formed over the substrate and having a portion spatially corresponding to the photosensitive element;
a color filter formed over the light shield layer; and
a microlens having a first microlens portion and a second microlens portion formed spaced apart over the color filter, the second microlens portion being formed in a region surrounded by the first microlens portion.

2. The image sensor of claim 1, further comprising an interlayer insulating film formed between the substrate and the light shield layer.

3. The image sensor of claim 2, further comprising an element protecting film formed over the interlayer insulating film.

4. The image sensor of claim 1, further comprising a planarization film formed over the color filter.

5. The image sensor of claim 1, further comprising a first interlayer insulating film formed over the substrate and a second interlayer insulating film formed over the first interlayer insulating film.

6. The image sensor of claim 5, wherein the light shield layer is formed in the second interlayer insulating film.

7. The image sensor of claim 6, further comprising an element protecting film formed over the second interlayer insulating film including the light shield layer.

8. The image sensor of claim 1, further comprising a field insulating film formed in the substrate.

9. The image sensor of claim 1, further comprising a planarization film formed over the color filter, wherein the microlens is formed over the planarization film.

10. A method for manufacturing an image sensor comprising:
forming a photosensitive element in a substrate; and then
forming a light shield layer over the substrate and having a portion spatially corresponding to the photosensitive element; and then
forming a color filter over the light shield layer; and then
forming a microlens having a first microlens portion and a second microlens portion spaced apart over the color filter, the second microlens portion being formed in a region surrounded by the first microlens portion.

11. The method of claim 10, further comprising, after forming the microlens:
monitoring overlay alignment between the first microlens portion and the second microlens portion.

12. The method of claim 10, further comprising, after forming the photosensitive element and before forming the light shield layer:
forming an interlayer insulating film over the substrate including the photosensitive element; and then forming an element protecting film over the interlayer insulating film.

13. The method of claim 10, further comprising, after forming the color filter and before forming the microlens:
forming a planarization film over the color filter, wherein the microlens is formed over the planarization film.

14. The method of claim 10, further comprising, after forming the photosensitive element and before forming the light shield layer:
forming a first interlayer insulating film over the substrate; and then
forming a second interlayer insulating film formed over the first interlayer insulating film.

15. The method of claim 14, wherein the light shield layer is formed in the second interlayer insulating film.

16. The method of claim 14, further comprising, after forming the light shield layer and before forming the color filter:
forming an element protecting film over the second interlayer insulating film including the light shield layer.

17. The method of claim 10, further comprising, before forming the photosensitive element:
forming a field insulating film in the substrate.

18. The method of claim 10, further comprising, after forming the color filter and before forming the microlens:
forming a planarization film over the color filter, wherein the microlens is formed over the planarization film.

19. A method comprising:
providing a substrate having a photosensitive element and a field insulating film formed therein; and then
forming a first interlayer insulating film over the substrate including the photosensitive element and the field insulating film; and then
forming a second interlayer insulating film formed over the first interlayer insulating film; and then
forming a light shield layer in the second interlayer insulating film; and then
forming an element protecting film over the second interlayer insulating film including the light shield layer; and then
forming a color filter over the element protecting film; and then
forming a microlens by forming a first microlens portion and a second microlens portion spaced apart over the color filter such that the second microlens portion is surrounded by the first microlens portion; and then
monitoring overlay alignment between the first microlens portion and the second microlens portion.

20. The method of claim 19, further comprising, after forming the color filter and before forming the microlens:
forming a planarization film over the color filter, wherein the microlens is formed over the planarization film.
